(19) United States
(12) Patent Application Publication
(10) Pub. No.: US 2019/0341468 A1
(43) Pub. Date: Nov. 7, 2019

(54) METHOD FOR FORMING AND TRIMMING GATE CUT STRUCTURE

(71) Applicant: GLOBALFOUNDRIES Inc., Grand Cayman (KY)

(72) Inventors: Hui Zang, Guilderland, NY (US); Laertis Economikos, Wappingers Falls, NY (US); Ruilong Xie, Niskayuna, NY (US)

(21) Appl. No.: 15/971,043

(22) Filed: May 4, 2018

(51) Int. Cl. H01L 29/66; H01L 21/8234; H01L 29/06; H01L 21/3213; H01L 21/28

(52) U.S. Cl. CPC H01L 29/66545; H01L 21/823431; H01L 29/0649; H01L 21/823437; H01L 21/0276; H01L 21/823462; H01L 21/28185; H01L 29/6656; H01L 21/28088; H01L 21/32133

(57) ABSTRACT

A method includes forming a semiconductor device including a plurality of fins formed above a substrate, an isolation structure positioned between the plurality of fins, a plurality of sacrificial gate structures defining gate cavities, and a first dielectric material positioned between the sacrificial gate structures. A gate cut structure is formed in a first gate cavity. A trim etch process is performed to reduce a width of the gate cut structure. Replacement gate structures are formed in the gate cavities after performing the trim etch process. A first replacement gate structure in the first gate cavity is segmented by the gate cut structure.

### BACKGROUND OF THE INVENTION

### 1. Field of the Invention

The present disclosure generally relates to the fabrication of integrated circuits, and, more particularly, to various methods of forming and trimming a gate cut structure.

### 2. Description of the Related Art

In modern integrated circuits, such as microprocessors, storage devices and the like, a very large number of circuit elements, especially transistors, are provided on a restricted chip area. Transistors come in a variety of shapes and forms, e.g., planar transistors, FinFET transistors, nanowire devices, etc. The transistors are typically either NMOS (NFET) or PMOS (PFET) type devices wherein the “N” and “P” designation is based upon the type of dopants used to create the source/drain regions of the devices. So-called CMOS (Complementary Metal Oxide Semiconductor) technology or products refers to integrated circuit products that are manufactured using both NMOS and PMOS transistor devices. Irrespective of the physical configuration of the transistor device, each device comprises drain and source regions and a gate electrode structure positioned above and between the source/drain regions. Upon application of an appropriate control voltage to the gate electrode, a conductive channel region forms between the drain region and the source region.

FIG. 1 is a perspective view of an illustrative prior art integrated circuit product 100 that is formed above a semiconductor substrate 105. In this example, the product 100 includes five illustrative fins 110, 115, a shared gate structure 120, a sidewall spacer 125 and a gate cap 130. The product 100 implements two different FinFET transistor devices (N-type and P-type) with a shared gate structure. The gate structure 120 is typically comprised of a layer of insulating material (not separately shown), e.g., a layer of high-k insulating material or silicon dioxide, and one or more conductive material layers (e.g., metal and/or polysilicon) that serve as the gate electrode for the transistors on the product 100. The fins 110, 115 have a three-dimensional configuration. The portions of the fins 110, 115 covered by the gate structure 120 define the channel regions of the FinFET transistor devices on the product 100. An isolation structure 135 is formed between the fins 110, 115. The fins 110 are associated with a transistor device of a first type (e.g., N-type), and the fins 115 are associated with a transistor device of a complementary type (e.g., P-type). The gate structure 120 is shared by the N-type and P-type transistors, a common configuration for memory products, such as static random access memory (SRAM) cells.

Typically, fins are formed in a regular array. An array of sacrificial gate structures is formed above the fins. Subsequently, a gate cut or “CT cut” process is performed to cut the sacrificial gate structures in the cross direction, for example between the fins 110, 115 for a device without a shared gate electrode. A dielectric material is formed in the gate cut recess. Subsequently, the sacrificial gate structures are removed and replacement gate structures (e.g., high-k gate dielectric and metal) are formed. In aggressively scaled devices, it is difficult to create a gate cut opening between the fins 110, 115 due to the small space therebetween. In some instances, the gate cut etch process may not completely etch through the gate structure, causing a gate-to-gate short. In other instances, the CD of the gate cut recess and subsequent gate cut structure may be such that it is difficult to form work function materials (WFM) and metal conductive fill materials without forming voids adjacent the gate cut structure.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods for forming and trimming a gate cut structure for FinFET semiconductor devices and the resulting devices. One illustrative method includes, among other things, forming a semiconductor device including a plurality of fins formed above a substrate, an isolation structure positioned between the plurality of fins, a plurality of sacrificial gate structures defining gate cavities, and a first dielectric material positioned between the sacrificial gate structures. A gate cut structure is formed in a first gate cavity. A trim etch process is performed to reduce a width of the gate cut structure. Replacement gate structures are formed in the gate cavities after performing the trim etch process. A first replacement gate structure in the first gate cavity is segmented by the gate cut structure.

Another illustrative method includes, among other things, forming a semiconductor device including a plurality of fins formed above a substrate, an isolation structure positioned between the plurality of fins, a plurality of sacrificial gate structures defining gate cavities, and a first dielectric material positioned between the sacrificial gate structures. A liner layer is formed in the gate cavities. A patterning layer is formed above the first dielectric material and in the gate cavities. The patterning layer has a first opening positioned above and extending into a first portion of the first gate cavity positioned between first and second subsets of the plurality of fins. A second dielectric material is formed in the first opening and in the first portion of the first gate cavity to form a gate cut structure. The patterning layer and the liner layer are removed from the gate cavities. A trim etch process is performed to reduce a width of the gate cut structure. Replacement gate structures are formed in the gate cavities. A first replacement gate structure in the first gate cavity is segmented by the gate cut structure.

### BRIEF DESCRIPTION OF THE DRAWINGS

The disclosure may be understood by reference to the following description taken in conjunction with the accompanying drawings, in which like reference numerals identify like elements, and in which:

FIG. 1 is a perspective view of one illustrative embodiment of a prior art semiconductor product; and

FIGS. 2A-2H depict one illustrative method disclosed for forming and trimming a gate cut structure for FinFET semiconductor devices and the resulting devices.

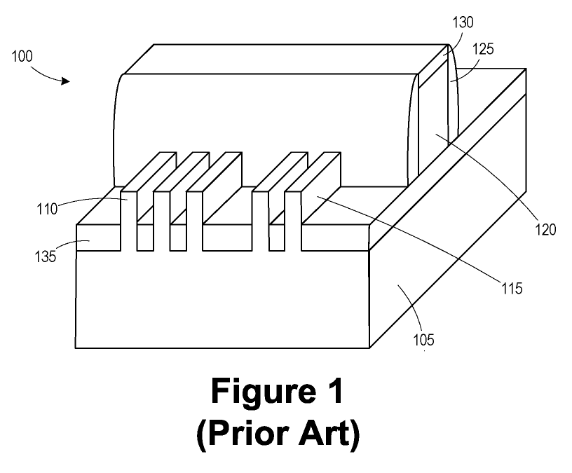

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming and trimming a gate cut structure for FinFET semiconductor devices and the resulting devices. Moreover, as will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. The methods and devices disclosed herein may be employed in manufacturing products using a variety of technologies, e.g., NMOS, PMOS, CMOS, etc., and they may be employed in manufacturing a variety of different devices, e.g., memory devices, logic devices, ASICs, etc. As will be appreciated by those skilled in the art after a complete reading of the present application, the inventions disclosed herein may be employed in forming integrated circuit products using a variety of so-called 3D devices, such as FinFETs.

The inventions disclosed herein should not be considered to be limited to the illustrative examples depicted and described herein. With reference to the attached figures, various illustrative embodiments of the methods and devices disclosed herein will now be described in more detail.

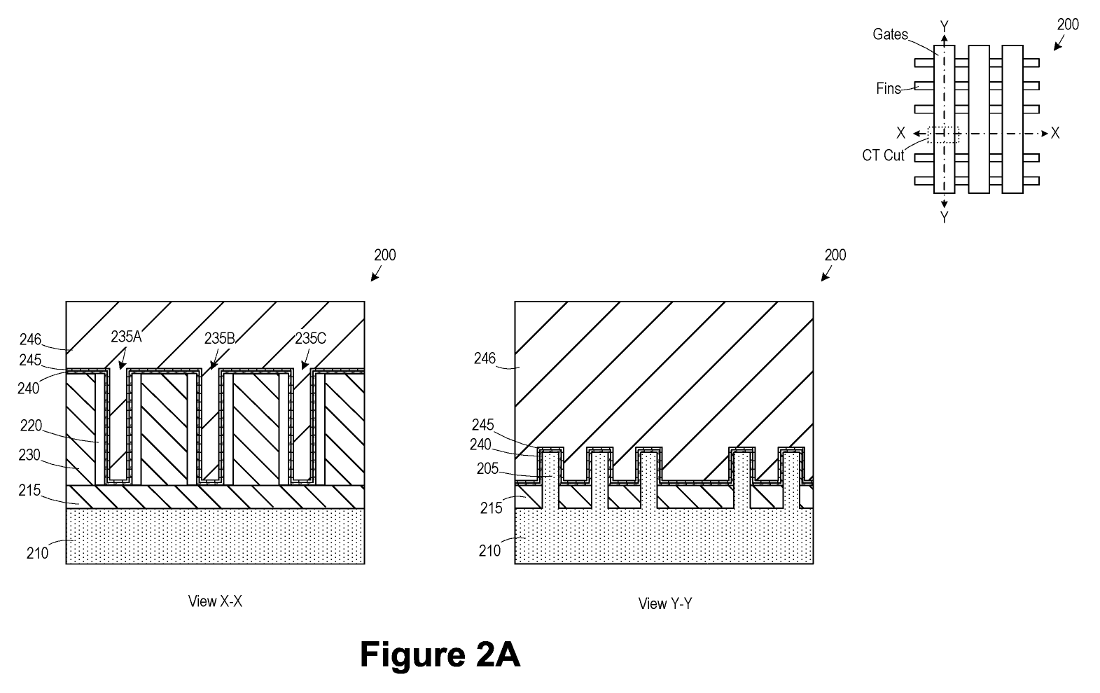

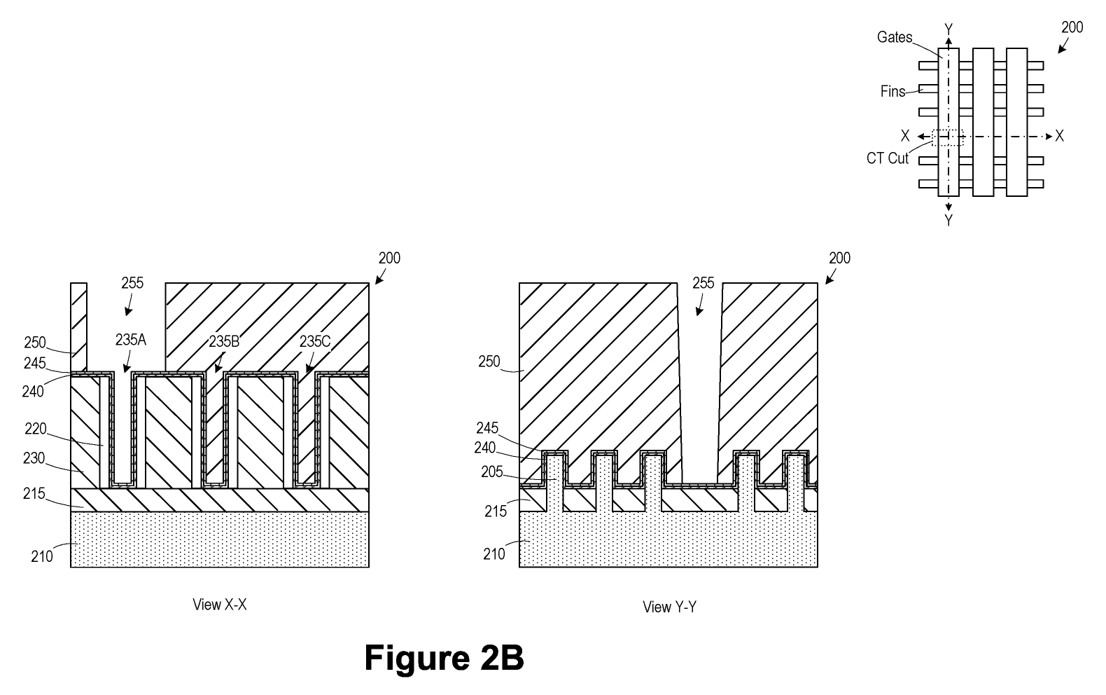

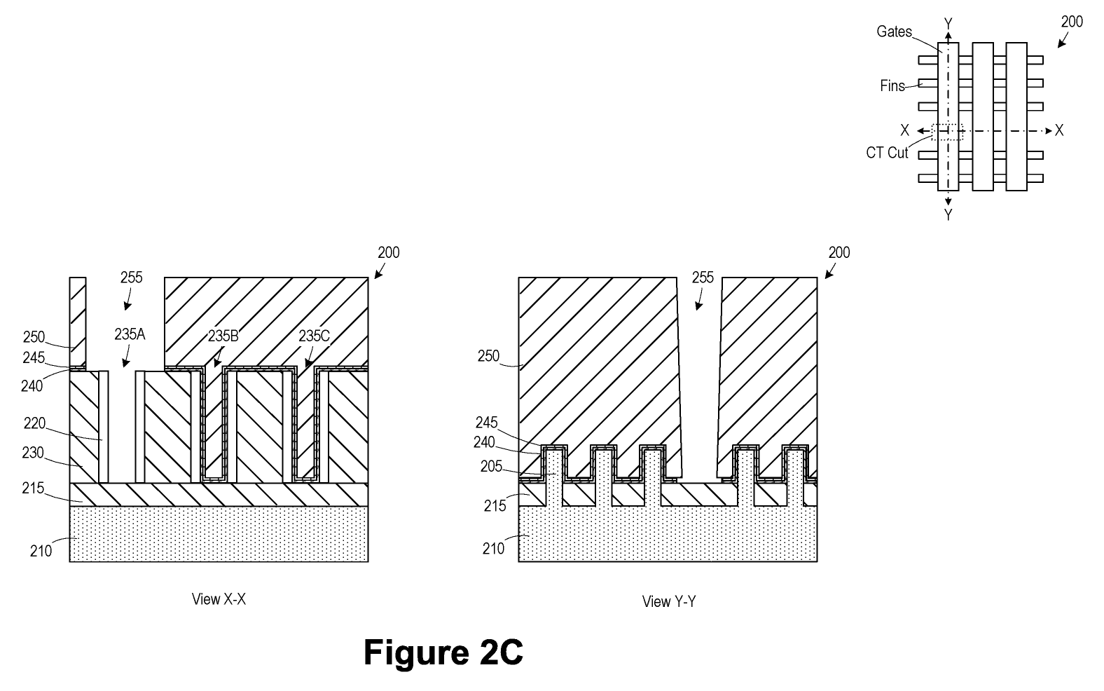

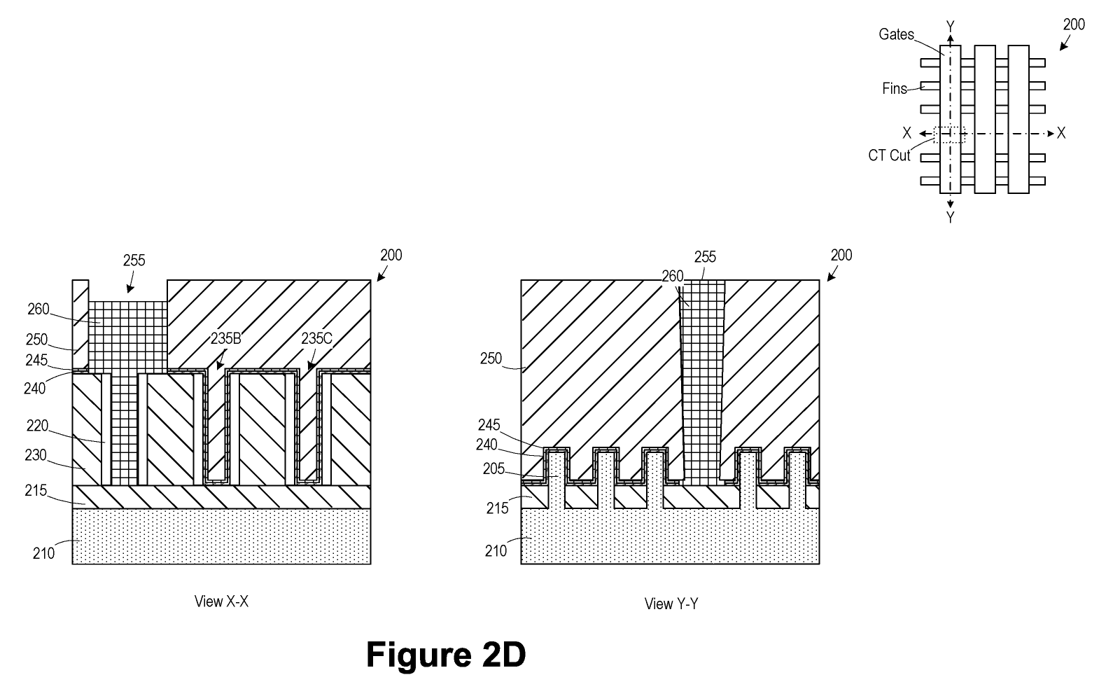

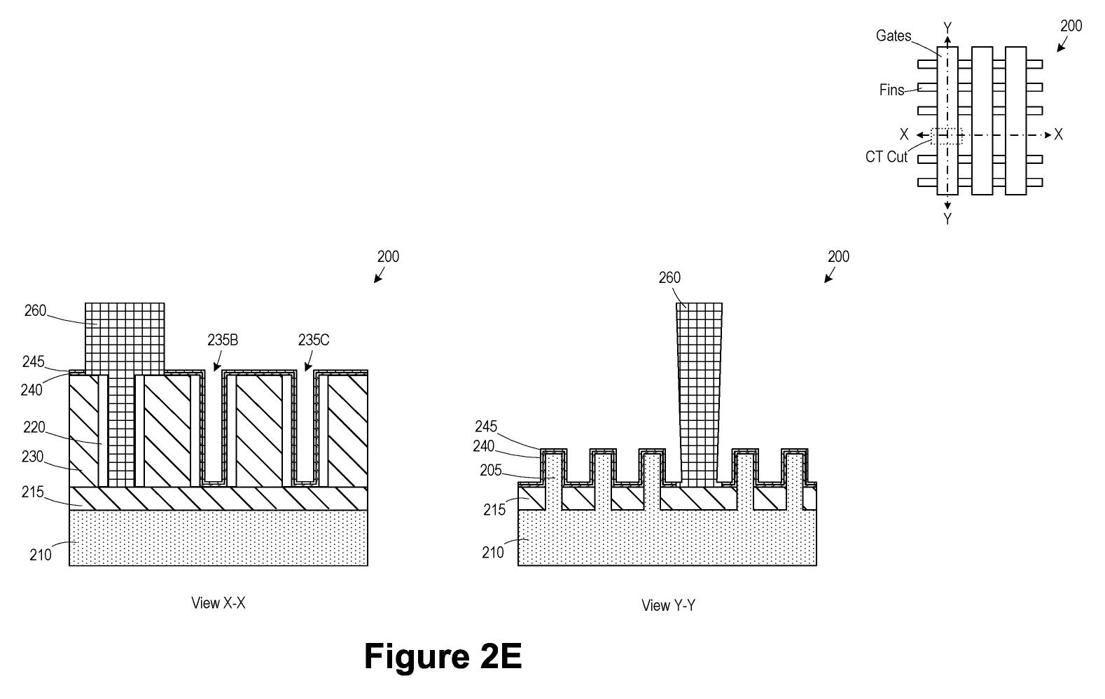

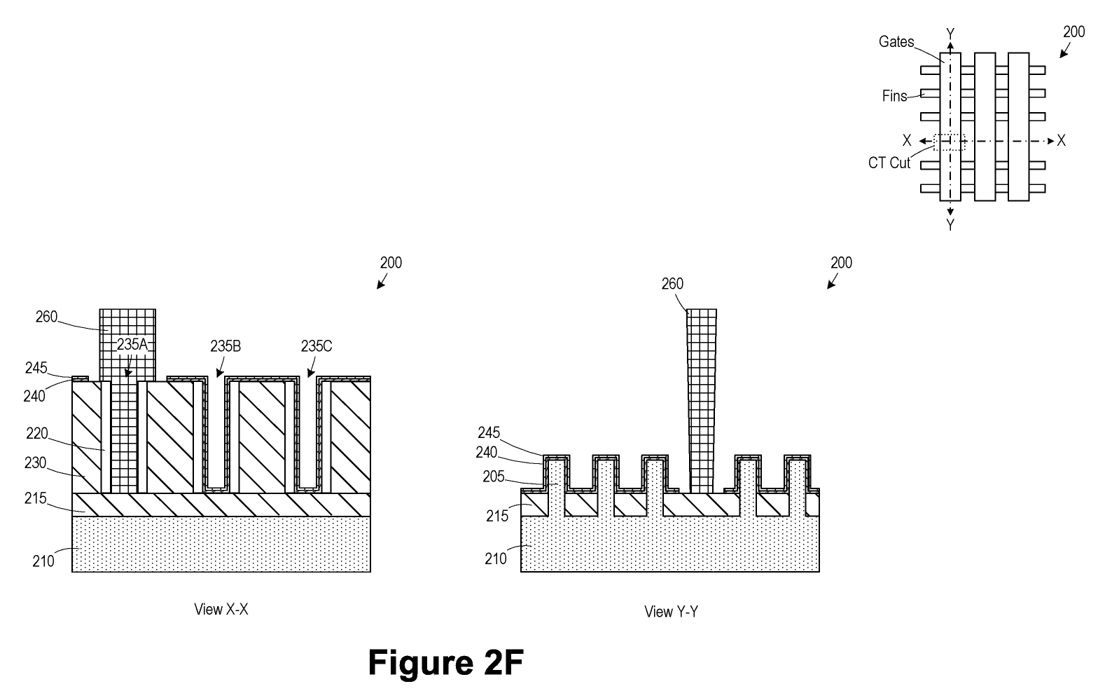

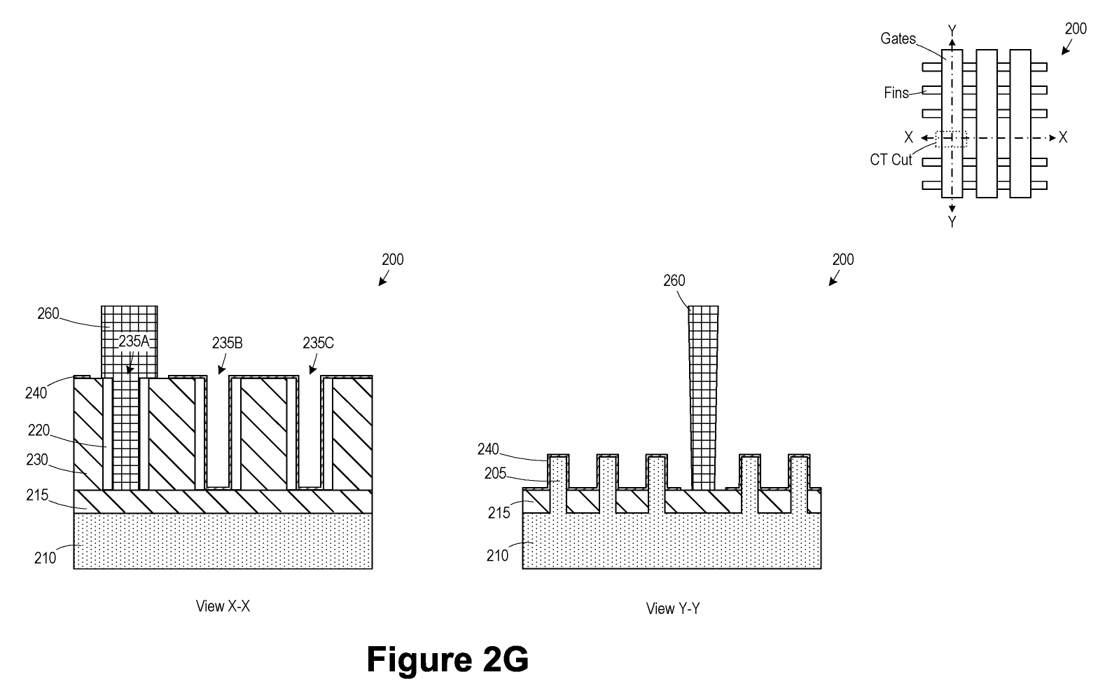

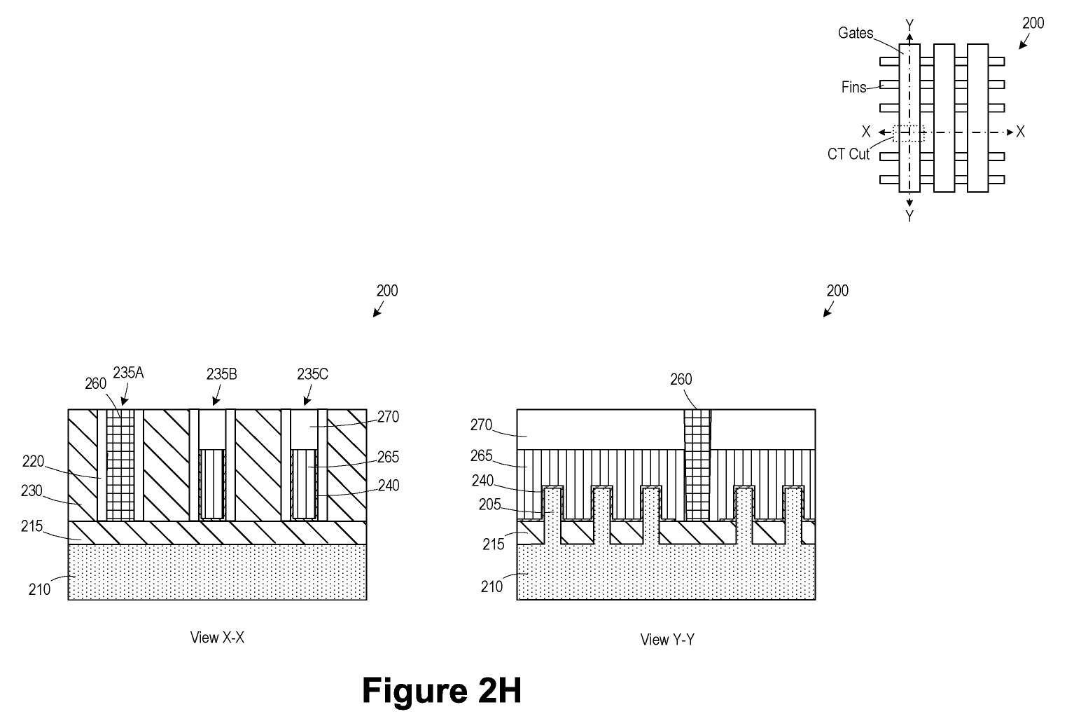

FIGS. 2A-2M depict one illustrative method disclosed for forming and trimming a gate cut structure for FinFET semiconductor devices and the resulting devices. The illustrative product 200 includes a plurality of fins 205 formed in a semiconductor substrate 210. The substrate 210 may have a variety of configurations, such as the depicted bulk silicon configuration. The substrate 210 may also have a silicon-on-insulator (SOI) configuration that includes a bulk silicon layer, a buried insulation layer and an active layer, wherein semiconductor devices are formed in and above the active layer. The substrate 210 may be formed of silicon or silicon germanium or it may be made of materials other than silicon, such as germanium. Thus, the terms “substrate” or “semiconductor substrate” should be understood to cover all semiconducting materials and all forms of such materials. The substrate 210 may have different layers.

FIG. 2A depicts the product 200 at a point in fabrication wherein several process operations have been performed. First, the plurality of fins 205 were formed. In general, the fins 205 define an active region for forming devices, such as FinFET transistors. An isolation structure (e.g., STI) 215 was formed by depositing a dielectric layer (e.g., silicon dioxide) between the fins and recessing the dielectric layer. Next, first sacrificial gate structures (not shown) were formed and sidewall spacers 220 were formed thereon to define placeholder gate structures. Additional dielectric material 230 (e.g., silicon dioxide) was deposited between the fins and planarized to expose the sacrificial gate structures. An etch process was performed to remove the sacrificial gate structures to define gate cavities 235A, 235B, 235C. A plurality of deposition processes were performed to line the gate cavities 235A, 235B, 235C with a gate insulation layer 240 (e.g., silicon dioxide or a high-k dielectric material, such as hafnium oxide), a liner layer 245 (e.g., TiN), and a sacrificial layer 246 (e.g., amorphous silicon). A reliability anneal process was performed on the gate insulation layer 240.

FIGS. 2A-2M also include a simplistic plan view of the product 200 (in the upper right corner of each sheet) that depicts the location where various cross-sectional views depicted in the following drawings will be taken. More specifically, the cross-sectional view “X-X” is taken perpendicular to the long axis of the gate structures in a region where a gate cut (i.e., CT cut) is to be performed. The cross-sectional view “Y-Y” is taken along the long axis of a gate structure where the CT cut is to be performed. Not all of the features illustrated in the views “X-X” and “Y-Y” are replicated in the simplistic plan view.

FIG. 2B illustrates the product 200 after a plurality of processes were performed. An etch process was performed to remove the sacrificial layer 246 and a deposition process was performed to form an organic patterning layer 250 (e.g., OPL) in the gate cavities 235A, 235B, 235C and above the dielectric material 230. A photolithography patterning process was performed (e.g., using a hard mask layer, a bottom anti-reflective coating (BARC) layer, and a photoresist layer) to etch the organic patterning layer 250 to define a gate cut opening 255 in the gate cavity 235A.

FIG. 2C illustrates the product 200 after one or more etch processes were performed to remove exposed portions of the gate insulation layer 240 and the liner layer 245 from the gate cavity 235A through the gate cut opening cavity 255.

FIG. 2D illustrates the product 200 after a deposition process was performed to deposit a dielectric material (e.g., silicon nitride) in the gate cut opening 255 to define a gate cut structure 260 and a recess etch process was performed to remove portions of the dielectric material extending beyond the gate cut opening 255.

FIG. 2E illustrates the product 200 after an ashing process was performed to remove the organic patterning layer 250. The spacers 220 support the gate cut structure 260 in the gate cavity 235A. The liner layer 245 protects the gate insulation layer 240 during the removal of the organic patterning layer 250.

FIG. 2F illustrates the product 200 after a trim etch process was performed to reduce the width of the gate cut structure 260. In some embodiments, the trim etch may be a timed isotropic etch.

FIG. 2G illustrates the product 200 after an etch process was performed to remove the liner layer 245.

FIG. 2H illustrates the product after several processes were performed to form replacement gate structures 265 in the gate cavities 235B, 235C. Several deposition processes may be performed to form various layers of the replacement gate structures 265, such as work function material layer (e.g., TiN for P-type devices or TiAlC for N-type devices) and a conductive fill material (e.g., tungsten). A planarization process was performed to remove portions of the replacement gate structures 265 and the gate cut structure 260 extending outside the gate cavities 235A, 235B, 235C. An etch process was performed to recess the replacement gate structures 265, and a deposition process was performed to form a cap layer 270 above the replacement gate structures 265.

In an alternative embodiment, the gate cut structure 260 may be formed prior to forming the gate insulation layer 240. In such an embodiment, the liner layer 245 would be formed in the gate cavities 235A, 235B, 235C, and the reliability anneal would not be performed initially. The gate insulation layer 240 would be formed after the removal of the liner layer 245 in FIG. 2C as part of the gate replacement process.

Additional process steps may be formed to complete fabrication of the product 200, such as the forming of source/drain contacts, and metallization layers including interconnects for contacting the various portions of the product, such as the source/drain regions, gate structures, etc. The process flow illustrated above has several advantages. Because the gate cut structure 260 is formed and trimmed prior to forming the replacement gate structures 265, the separation between the gate cut structure 260 and the fins 205 is better controlled, thereby increasing the process margin for forming the replacement gate structures 265.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method, comprising:
forming a semiconductor device comprising a plurality of fins formed above a substrate, an isolation structure positioned between said plurality of fins, a plurality of sacrificial gate structures defining gate cavities, and a first dielectric material positioned between said plurality of sacrificial gate structures;
forming a gate cut structure in a first gate cavity;
performing a trim etch process to reduce a width of said gate cut structure; and
forming replacement gate structures in said gate cavities after performing said trim etch process, wherein a first replacement gate structure in said first gate cavity is segmented by said gate cut structure.

2. The method of claim 1, wherein forming said gate cut structure comprises:
forming a liner layer in said gate cavities;
forming a patterning layer above said first dielectric material and in said gate cavities, said patterning layer having a first opening positioned above and extending into a first portion of said first gate cavity positioned between first and second subsets of said plurality of fins;
forming a second dielectric material in said first opening and in said first portion of said first gate cavity to form a gate cut structure;
removing said patterning layer and said liner layer from said gate cavities; and
performing said trim etch process to reduce a width of said gate cut structure.

3. The method of claim 2, further comprising:
forming a gate insulation layer in said gate cavities prior to forming said liner layer; and
performing an anneal process on said gate insulation layer.

4. The method of claim 3, wherein said gate insulation layer comprises a high-k dielectric material.

5. The method of claim 3, wherein forming said replacement gate structure further comprises:
forming a conductive material in said gate cavities above said gate insulation layer;
recessing said conductive material; and
forming a cap layer in said gate cavities above said recessed conductive material.

6. The method of claim 3, further comprising:
forming a sacrificial material in said gate cavities above said liner layer;
performing said anneal process after forming said sacrificial material; and
removing said sacrificial material prior to forming said patterning layer.

7. The method of claim 2, wherein forming said replacement gate structure further comprises:
forming a gate insulation layer in said gate cavities; and
forming a conductive material in said gate cavities above said gate insulation layer.

8. The method of claim 7, further comprising:
recessing said conductive material; and
forming a cap layer in said gate cavities above said recessed conductive material.

9. The method of claim 1, further comprising:
forming a sacrificial material layer above said plurality of fins;
patterning said sacrificial material layer to define a plurality of sacrificial electrodes;
forming spacers on said sacrificial electrodes; and
removing said sacrificial electrodes to define said gate cavities between adjacent spacers.

10. The method of claim 1, wherein said first replacement gate structure comprises a first portion positioned above said first subset and a second portion positioned above said second subset, wherein said gate cut structure is positioned between said first and second portions of said first replacement gate structure.

11. A method, comprising:
forming a semiconductor device comprising a plurality of fins formed above a substrate, an isolation structure positioned between said plurality of fins, a plurality of sacrificial gate structures defining gate cavities, and a first dielectric material positioned between said plurality of sacrificial gate structures;
forming a liner layer in said gate cavities;
forming a patterning layer above said first dielectric material and in said gate cavities, said patterning layer having a first opening positioned above and extending into a first portion of a first gate cavity positioned between first and second subsets of said plurality of fins;
forming a second dielectric material in said first opening and in said first portion of said first gate cavity to form a gate cut structure;
removing said patterning layer and said liner layer from said gate cavities;
performing a trim etch process to reduce a width of said gate cut structure; and
forming replacement gate structures in said gate cavities, wherein a first replacement gate structure in said first gate cavity is segmented by said gate cut structure.

12. The method of claim 11, further comprising:
forming a gate insulation layer in said gate cavities prior to forming said liner layer; and
performing an anneal process on said gate insulation layer.

13. The method of claim 12, wherein said gate insulation layer comprises a high-k dielectric material.

14. The method of claim 12, further comprising:
forming a sacrificial material in said gate cavities above said liner layer;
performing said anneal process after forming said sacrificial material; and
removing said sacrificial material prior to forming said patterning layer.

15. The method of claim 12, wherein forming said replacement gate structure further comprises:
forming a conductive material in said gate cavities above said gate insulation layer;
recessing said conductive material; and
forming a cap layer in said gate cavities above said recessed conductive material.

16. The method of claim 11, wherein forming said replacement gate structure further comprises:
forming a gate insulation layer in said gate cavities; and
forming a conductive material in said gate cavities above said gate insulation layer.

17. The method of claim 16, further comprising:
recessing said conductive material; and
forming a cap layer in said gate cavities above said recessed conductive material.

18. The method of claim 11, further comprising:
forming a sacrificial material layer above said plurality of fins;
patterning said sacrificial material layer to define a plurality of sacrificial electrodes;
forming spacers on said sacrificial electrodes; and
removing said sacrificial electrodes to define said gate cavities between adjacent spacers.

19. The method of claim 11, wherein said first replacement gate structure comprises a first portion positioned above said first subset and a second portion positioned above said second subset, wherein said gate cut structure is positioned between said first and second portions of said first replacement gate structure.
